(19) United States
(12) Patent Application Publication
(10) Pub. No.: US 2009/0120666 A1
(43) Pub. Date: May 14, 2009

(54) Clad Contact Point Material and Method for Mounting a Clad Contact Point Material

(76) Inventor: Hideaki Takeda, Misato (JP)

Correspondence Address: SCHWEGMAN, LUNDBERG & WOESSNER, P.A., P.O. BOX 2938, MINNEAPOLIS, MN, 55402, US

(21) Appl. No.: 12/225,511

(22) PCT Filed: Mar. 8, 2007
(86) PCT No.: PCT/JP2007/000182

§ 371 Date: Sep. 23, 2008

(30) Foreign Application Priority Data
Mar. 24, 2006 (JP) 2006-082081

(51) Int. Cl. H01B 5/00; H05K 3/00

(52) U.S. Cl. 174/126.1; 29/845

(57) ABSTRACT

A clad contact point material 1 is formed into a tape in shape by attaching by pressure a contact point part 3 of silver or silver nickel to a copper base material 2, silver plating 4 is performed on the entire material. A 2 mm clad contact point 6 segmented from the clad contact point material 1 is pushed into a lower hole 8 provided at the end part of a 0.15 mm thick beryllium copper movable plate 7 caulked as shown in FIG. 2D, and mounted as a contact point. Since the caulked part includes more silver plated part at the ratio of 1:1.3, it is antioxidant and anticorrosive under a high temperature condition, thereby increasing a service life of the contact point, and realizing uses under higher temperature and larger current conditions.

### TECHNICAL FIELD

The present invention relates to a clad contact point material for realizing a widely used clad contact point and a method for mounting the clad contact point material.

### BACKGROUND ART

A conventional method of mounting a contact point on a base metal by caulking is roughly divided into a method of caulking a contact point processed as a rivet in a base metal and a composite processing method of simultaneously performing punching and caulking by providing a wire-shaped contact point material for a pressing mold.

In the method of caulking a rivet-type contact point on a base metal, a contact point material is first mounted in rivet form on a base material by header processing to make a rivet-type contact point.

Then, the base material part is inserted into a hole formed in the base metal, and the end part of the base material part that is projected beyond the hole is squeezed by pressure and caulking, thereby mounting the rivet-type contact point on the base metal. The rivet-type contact point is commonly processed by silver plated in advance.

In the meantime, composite processing capable of performing composite processing using high-speed pressing has been commonly used to produce a large amount of base metal with a contact point. A wire-shaped contact point material can be a single wire or a clad material obtained by laminating a contact point material with a base material.

Since a clad material can be configured with a smaller amount of contact point material made of precious metal by the amount of inexpensive base material for lamination, contact point cladding has been performed at an early stage.

When the clad material is used, the clad material is processed into a thin tape-shaped strip material and finished as a contact point tape. While cutting the contact point tape by slit processing, a thin square contact point is prepared, and the contact point is inserted into the hole in the base metal and squeezed by pressure from both sides of the base metal, thereby caulking the contact point on the base metal.

Since the contact point tape is in tape form, it has been mounted on a base metal as is, and has not been plated in advance. (Refer to, for example, Japanese Published Patent Application No. S54-150678, FIG. 9, and Japanese Published Patent Application No. S56-050010, FIGS. 18 and 21.)

Generally, when a contact point is energized, Joule heat generated by contact resistance of a contact point raises the temperature of the contact point part. If a contact point is used under a higher temperature or larger current condition, the environmental temperature and the temperature rise abnormally raises the temperature of the contact point.

If the heat radiation develops on the base metal in this state, the contact point temperature reaches equilibrium. However, if the caulking level of a caulked part is low, and the contact resistance of the caulked part is high, it is hard to realize heat radiation of the contact point to the base metal, thereby further raising the contact point temperature.

When the temperature of the contact point becomes high, the cooling capability of an open/close arch is reduced, and the power cutoff capability of the contact point is degraded. In addition, the oxidation on the surface of the contact point itself easily develops by the high temperature. Especially, the base metal is formed by a copper material, and the surface of the caulking by press processing on a clad material contact point is a cut surface or a broken surface.

Regardless of a rivet type or a clad material type, a contact point of a contact point material and a base material has a copper base material in many cases. Therefore, surface oxidation easily develops.

The caulking level of a rivet-type contact point is high because the caulking is performed by squeezing only a leg part (base part), and a caulked part is tightly close to the mounting part of the base metal. Therefore, the contact resistance is low and the progress of the oxidation of a contact part is not fast.

However, press processing which is different from the method for a rivet-type contact point is performed on a clad contact point, the caulking level is low, and it is different to improve the level.

Thus, since the caulking level of a clad contact point is low, the area of the contact with the base metal is necessarily small, thereby causing lower closeness to the base metal and easily supplying oxygen to the contact part. In addition, there occurs larger contact resistance and a high temperature, and oxidation easily develops on both sides.

Therefore, the clad contact point has no problem when it is made within a predetermined range, but under a higher temperature or larger current condition, it has no flexible performance and can be used with restrictions.

The present invention has been developed to overcome the above-mentioned problems, and aims at providing a clad contact point material and a method for mounting a clad contact point material to realize a clad contact point for a wide range of uses.

### DISCLOSURE OF THE INVENTION

The clad contact point material according to the first invention is formed by attaching by pressure an electric contact point material mainly composed of precious metal on a base material of electroconductive metal into a tape-shaped member, a contact point object segmented to have a predetermined length is hammered onto a base metal of a plate material formed by press processing by composite processing and caulked, and the contact point object is formed as an electric contact point on the base metal. The entire surface of the tape-shaped member is covered with antioxidant metal.

With the clad contact point material, for example, the electric contact point material is silver or a silver alloy, the base material is copper or a copper alloy, and the antioxidant metal is silver or gold.

In addition, for example, a metal intermediate layer having alloy retardant properties with at least the electric contact point material is provided between the contact point material and the base material.

Next, the clad contact point material according to the second invention is configured as a tape-shaped member that can be segmented with a predetermined length by attaching by pressure or seam-welding a thin plate of an electric contact point material on a surface of a nickel-plated base material.

In the above-mentioned first or second invention, the thickness of the electric contact point material is half or less than the thickness of the base material.

Furthermore, in the method for mounting a clad contact point material according to the third invention the clad contact point material according to the first or second invention is used, a contact point object is hammered onto a base metal of a plate material formed by press processing by composite processing and caulked, and the contact point object is formed as an electric contact point on the base metal, wherein the segmentation length a of the contact point object segmented from the clad contact point material and the width b of the clad contact point material has the relationship of b<a.

In this case, for example, it is desired that the relationship between the length a of the contact point object and the width b of the clad contact point material is at least a:b=1.3:1.

In the method for mounting a clad contact point material, the contact point object is hammered onto the base metal of the plate material formed by press processing by composite processing and caulked, and the base material is caulked to the base material.

As described above, according to the present invention, since the area larger than the cut area of the base material of the caulked part is plated by antioxidant and electroconductive metal, the progress of the oxidation of the caulked part, and the progress of the damage of a contact point, thereby extending the service life of the contact point.

In addition, since at least a contact point material and alloy retardant metal are inserted between the contact point material and the base material, the melting point of the contact point can be prevented from being lowered by alloyed contact point material, thereby reducing melting or damaging the contact point by a spark or a higher temperature, and contributing not only to an extended service life of the contact point but also to an effective use as a contact point of a temperature switch and a relay used in a higher temperature area.

Additionally, since the base material is plated with nickel not lowering a melting point when it is alloyed with copper most frequently used as a base material, and not alloyed with silver frequently used as a contact point material, a melting point can be prevented from being lowered, the service life of the contact point can be extended, and an effective contact point of a temperature service and a relay for use in a higher temperature area can be realized.

### BRIEF DESCRIPTION OF THE DRAWINGS

FIG. 1 is a perspective view of a tape-shaped clad contact point material as an embodiment 1;

FIG. 2A shows the method for mounting a clad contact point material using the clad contact point material according to the embodiment 1;

FIG. 2B shows the method for mounting a clad contact point material using the clad contact point material according to the embodiment 1;

FIG. 2C shows the method for mounting a clad contact point material using the clad contact point material according to the embodiment 1;

FIG. 2D shows the method for mounting a clad contact point material using the clad contact point material according to the embodiment 1;

FIG. 2E shows the method for mounting a clad contact point material using the clad contact point material according to the embodiment 1;

FIG. 3 shows an example of the configuration of the clad contact point material for a clad contact point where a melting point does not lower under a higher temperature condition according to the embodiment 2; and

FIG. 4 shows another example of the configuration of the clad contact point material for a clad contact point where a melting point does not lower under a higher temperature condition according to the embodiment 3.

### DESCRIPTIONS OF REFERENCE NUMERALS

1 clad contact point material
2 base material
3 contact point part
4 silver plating
5 slit processing part
6 clad contact point
7 movable plate
8 lower hole
10 clad contact point material
11 nickel
12 clad contact point material
13 contact point surface

### BEST MODE FOR CARRYING OUT THE INVENTION

### Embodiment 1

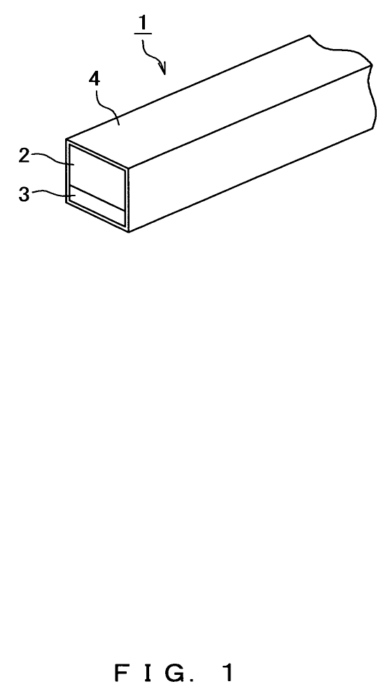

FIG. 1 is a perspective view of a tape-shaped clad contact point material as an embodiment 1. As shown in FIG. 1, a clad contact point material 1 according to the present embodiment is formed as a tape by attaching by pressure a silver or silver nickel contact point part 3, and the entire tape is processed by silver plating 4. The entire thickness of the clad contact point material 1 is 1.5 mm, and the plating thickness is 3 μm or more.

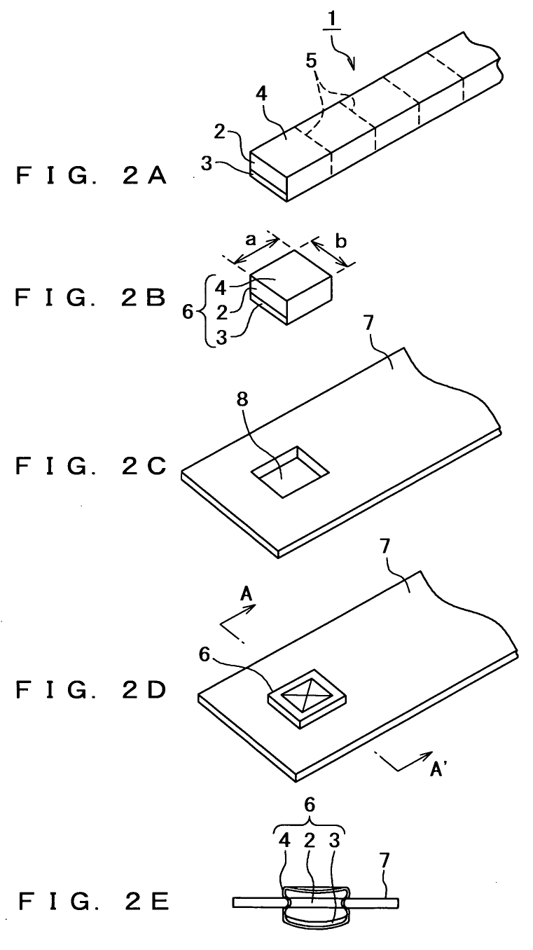

FIGS. 2A, 2B, 2C, 2D, and 2E show the method for mounting a clad contact point material by the clad contact point material 1 above. FIG. 2A briefly shows the clad contact point material 1 shown in FIG. 1.

The clad contact point material 1 is segmented as a clad contact point 6 as shown in FIG. 2B by cutting along a slit processing part 5 in the slit processing in the process of press processing.

The segmentation sizes of the clad contact point 6 are b=1.5 mm in width and a=2 mm in length. Thus, the ratio of the width to length is 1:1.333.

With the above-mentioned configuration, when the clad contact point 6 is mounted on a switch movable plate, the plating surface is larger than the cut surface, thereby incurring a dominant placing effect.

In mounting the clad contact point 6 on the switch movable plate, and in the press processing, as shown in FIG. 2C, a lower hole 8 is provided at the end part of a 0.15 mm thick beryllium copper movable plate 7, and the 2 mm long segmented clad contact point is pushed into the lower hole 8, caulked as shown in FIG. 2D, and mounted as a contact point.

FIG. 2E is a sectional view along the arrows A-A′ shown in FIG. 2D. Thus, the thickness of the contact point part 3 of the clad contact point 6 caulked and mounted on the movable plate 7 is ⅕ or less of the entire thickness.

When the clad contact point 6 is individually segmented from the tape-shaped clad contact point material 1, the copper base material 2 is exposed on the section.

If the silver plating 4 is not performed, the caulked part to the movable plate 7 is totally formed by the contact by pressure to the copper base material 2.

The clad contact point without silver plating is used as a contact point of a switch movable plate of a thermostat operating at, for example, 150° C., and when the 18A open/close test is conducted, the progress of the oxidation of the base material of a contact point becomes rapid.

With the progress of the oxidation and the increase of the contact resistance of the caulked part, the degradation of the contact point accelerates. Then, not only the progress of the coarse contact point surface, but also the unstable contact of the caulked part incurs the state of the inter terminal resistance exceeding several hundreds times to thousand times the value under a normal condition.

However, when the clad contact point 6 processed by the silver plating 4 according to the present embodiment is tested under the same condition, there is almost no color change on the contact point part, and the increase of the inter-terminal resistance can be reduced. As a result, a 1.5 time current increase can be realized.

Although silver is normally antioxidant, the silver used in the silver plating 4 is silver oxide generated by the reaction with highly oxidant ozone. The silver oxide has the properties of being decomposed by heat and discharging oxygen in the air. Using the properties, silver plating is performed.

Thus, in the present embodiment, the entire tape-shaped clad contact point material is plated with, for example, silver to prevent the oxidation of the clad contact point material. Since silver is antioxidant metal, and has low resistance to be used as a contact point, there is no problem when the entire clad contact point material is covered with plating. The antioxidant plating is effective in preventing the oxidation of the base material part in contact between a movable plate and a caulked part.

When gold that can be relatively easily plated with precious metal as with silver can be used as a plating material of the clad contact point material 1 to prevent the oxidation of the base material of the clad contact point and stabilize the contact resistance as in the case of silver.

In addition, other than precious metal, nickel is relatively antioxidant. Although nickel is used in plating, similar effects can be obtained although it is less effective than silver.

### Embodiment 2

Generally when a contact point is used under a larger current condition, the contact point reaches a high temperature. When a clad contact point having silver and copper attached by pressure at a contact point is used, and when the contact point reaches a high temperature, the dispersion of the silver and copper develops, and the alloying effect at the interface develops.

The eutectic temperature between silver and copper is 779° C., and silver and copper easily become an alloy when a contact point reaches a high temperature. When the alloying process develops, there occurs a high probability of welding at a contact point because the melting point of an alloy of silver and copper is lower than each single unit.

When silver and copper are alloyed, the melting point is lowered, and the contact point becomes coarse, the joint portion between the contact point material and the base material at a potion partially lower than the surface or the base material of the lower layer is exposed. Since an alloy rapidly develops at the portion, the properties of a contact point are considerably degraded.

The second embodiment presents a configuration of a contact point at which a lower melting point is prevented.

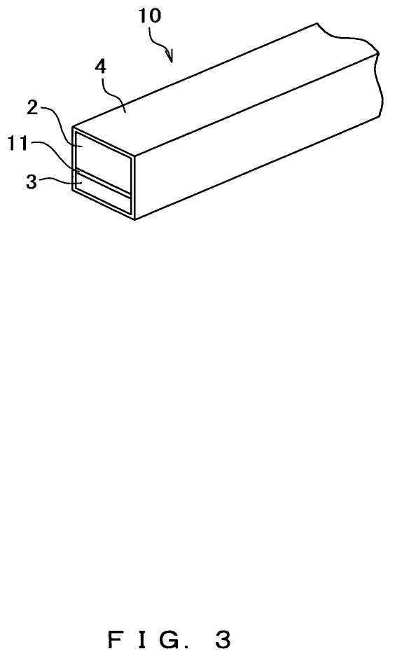

FIG. 3 shows an example of the configuration of the clad contact point material for a clad contact point where a melting point does not lower under a higher temperature condition according to the embodiment 2.

A clad contact point material 10 shown in FIG. 3 is multilayer material using nickel 11 as an intermediate metal layer on the interface, between the base material 2 of the clad contact point material having a similar configuration to that shown in FIG. 1, which is alloy retardant to one of the base material 2 and the contact point part 3. The method for mounting a clad contact point material using the clad contact point material 10 is similar to that shown in FIG. 2.

The nickel 11 has the properties of not lowering the melting point of the copper of the base material 2 when it becomes an alloy with the copper of the base material 2, and not making an alloy with the silver of the contact point part 3. Through the nickel 11, the copper of the base material 2 cannot make an alloy with the silver of the contact point part 3, thereby preventing the melting point of a contact point from being lowered.

Thus, in the present embodiment, since there is an intermediate layer metal, between the silver of the contact point part 3 and the copper of the base material, that is an alloy retardant metal to at least one of the silver and the copper, the problem of lowering the melting point of a contact point part can be suppressed because nickel can hardly make an alloy with silver when an intermediate layer nickel is used.

### Embodiment 3

The method of using an intermediate layer on the interface between the base material 2 and the contact point part 3 can be more easily realized, which is described below as the third embodiment.

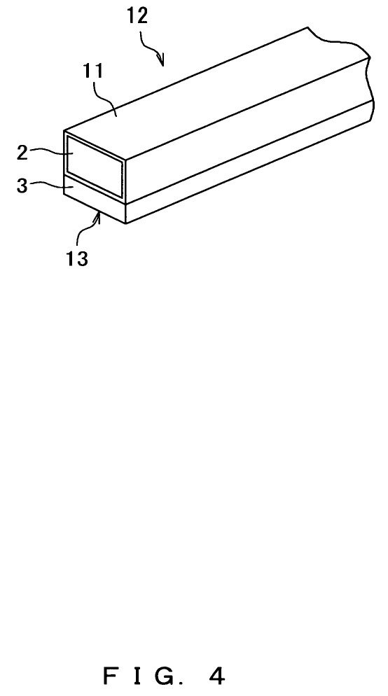

FIG. 4 shows another example of the configuration of the clad contact point material for a clad contact point where a melting point does not lower under a higher temperature condition according to the embodiment 3.

A clad contact point material 12 shown in FIG. 4 is covered by plating the base material 2 with the nickel 11 before joining the base material 2 with the base material 2. Then, the contact point part 3 is cold-pressed or seam-welded on the nickel plated surface of the base material 2.

Thus, a contact point surface 13 can be prevented from the oxidation of the base material 2 because the surface of the silver as the precious metal of the contact point part 3 can be maintained and the copper of the base material 2 of the clad is first plated with nickel.

In this method, the oxidation of the base material 2 is suppressed, the caulking contact part is stable, and the alloy between the silver of the contact point part 3 and the copper of the base material 2 can be restricted.

Thus, since the oxidation of the caulked part between the contact point material and the movable plate is suppressed, the melting point does not lower under a higher temperature or larger current condition, and faulty welding can be reduced, thereby expanding the electric rating of a less expensive clad contact point generated by composite processing, and realizing wide and economical uses.

### INDUSTRIAL APPLICABILITY

As described above, the clad contact point material and the method for mounting the clad contact point material can be used in all industries of producing clad contact points.

1. A clad contact point material formed by attaching by pressure an electric contact point material mainly composed of precious metal on a base material of electroconductive metal into a tape-shaped member, a contact point object segmented to have a predetermined length is hammered onto a base metal of a plate material formed by press processing by composite processing and caulked, and the contact point object is formed as an electric contact point on the base metal, wherein
an entire surface of the tape-shaped member is covered with antioxidant metal.

2. The material according to claim 1, wherein
the electric contact point material is silver or a silver alloy, the base material is copper or a copper alloy, and the antioxidant metal is silver or gold.

3. The material according to claim 1, wherein
a metal intermediate layer having alloy retardant properties with at least the electric contact point material is provided between the contact point material and the base material.

4. The material according to claim 1, wherein
a tape-shaped member is segmented with a predetermined length by attaching by pressure or seam-welding a thin plate of an electric contact point material on a surface of a nickel-plated base material.

5. The material according to claim 1, wherein
the thickness of the electric contact point material is half or less than the thickness of the base material.

6. A method for mounting a clad contact point material according to claim 1, a contact point object is hammered onto a base metal of a plate material formed by press processing by composite processing and caulked, and the contact point object is formed as an electric contact point on the base metal, wherein
a segmentation length a of the contact point object segmented from the clad contact point material and a width b of the clad contact point material has a relationship of b<a.

7. The method according to claim 6, wherein
a relationship between the length a of the contact point object and the width b of the clad contact point material is at least a:b=1.3:1.

8. The method according to claim 6, wherein
the contact point object is hammered onto the base metal of the plate material formed by press processing by composite processing and caulked, and the base material is caulked to the base material.
